(19) United States
(12) Patent Application Publication
(10) Pub. No.: US 2004/0222833 A1
(43) Pub. Date: Nov. 11, 2004

(54) High performance time division duplex radio frequency integrated circuit and operation method thereof

(76) Inventors: Tsung-Liang Lin, Hsinchu (TW); Chung-Ju Tsai, Hsinchu (TW); Jan-Kwo Leeng, Hsinchu (TW)

Correspondence Address: J.C. Patents, Inc., Suite 250, 4 Venture, Irvine, CA, 92618, US

(21) Appl. No.: 10/646,406

(22) Filed: Aug. 22, 2003

Related U.S. Application Data
(60) Provisional application No. 60/466,008, filed on Apr. 25, 2003.

(51) Int. Cl. H03L 7/00

(52) U.S. Cl. 327/162

(57) ABSTRACT

The embodiment of the present invention provides a joint clock source coupling architecture of a time division duplex (TDD) transceiver to minimize a circuit element interference and stabilize a performance of a circuit element within the TDD transceiver. Thereby, a communication link of the TDD transceiver is ensured, and a throughput of the TDD transceiver is increased.

### CROSS-REFERENCE TO RELATED APPLICATION

This application claims the priority benefits of U.S. provisional application titled “METHOD AND APPARATUS FOR IMPROVING PERFORMANCE OF A COMMUNICATION TRANSCEIVER” filed on Apr. 25. 2003, Ser. No. 60/466,008. All disclosure of this application is incorporated herein by reference.

### BACKGROUND OF THE INVENTION

1. Field of the Invention

The present invention pertains to a Radio Frequency Integrated Circuit (RF IC) in general, and more particularly to a crystal oscillator coupling method and apparatus that provides a common clock source to both analog and digital circuits in the RF IC.

2. Description of the Related Art

A wide range of communication systems uses an analog radio frequency signal in communicating with a remote host, and internally, instead of an analog signal, a digital signal flows through a signal processing device or a signal creation device of the communication systems. An advantage of digital systems has propagated through the communication systems except that a communication signal receiving and transmitting part of circuits still uses analog signal in carrying communication data. As depicted in FIG. 1, a time division duplex (TDD) transceiver 160 contains an analog circuit 130, an analog-to-digital (AID) and digital-to-analog (D/A) interface 140, and a digital circuit 150 in a block diagram 100. A design of a modem communication system commonly combines an analog circuit, an A/D and D/A interface, and a digital circuit together into an integrated circuit like a design of the TDD transceiver in FIG. 1. Mainly, the analog circuit is used for communication signal receiving and transmitting, and the digital circuit is used for digital signal processing and for forming a communication layer to a communication protocol stack. In between, the A/D and D/A interface is established for transforming an analog signal to a digital signal and a digital signal to an analog signal. With a pair of TDD transceiver communication systems depicted in FIG. 1, a communication medium can be a communication wire 120 connecting the two systems together or a pair of antenna 110 allowing communication signal propagating back and forth through the air.

As the analog circuit 130 and the digital circuit 150 of the TDD transceiver 160 are integrated together accompanying with the interface circuit 140, a circuit element interference complicatedly couples each circuit element together from an analog circuit to a digital circuit element and vice versa. The complicatedly circuit element interference sometimes unpredictably breaks a communication link integrity and suppresses a data throughput during communications. By carefully studying the circuit element interference, the embodiment of the present invention provides a joint clock coupling architecture that greatly reduces the circuit element interference, and stabilizes a performance of each circuit element in the TDD transceiver; thereby, a communication link integrity is ensured, and a data throughput of a communication link is noticeably increased.

### SUMMARY OF THE INVENTION

The preferred embodiment of the present invention is directed to a joint clock coupling architecture in a time division duplex (TDD)transceiver that contains an analog circuit, a digital circuit, and an analog-to-digital (A/D) and a digital-to-analog (D/A) interface circuit. The joint clock is a crystal oscillator that simultaneously supplies clock pulses to the analog circuit, the digital circuit, and the A/D and D/A interface circuit. The joint clock coupling architecture greatly reduces a circuit element interference, and stabilizes a circuit element performance in the TDD transceiver; thereby, a data throughput of a TDD transceiver communication link is increased, and a TDD transceiver communication link integrity is ensured.

The preferred embodiment of the present invention provides a method as well as a circuit architecture of minimizing a circuit element interference in a TDD transceiver. The method first provides a communication medium in which a communication signal propagates back and forth through it. The communication medium can be a wireless or a wiring medium. The method then constructs an analog circuit for receiving and transmitting the communication signal through the medium at a time. The analog circuit also modulates and demodulates the communication signal during a process of receiving and transmitting communication signal. In addition to the analog circuit, the method also constructs a digital circuit for digital signal processing and for forming a layer of a communication protocol stack. With the analog circuit and the digital circuit built, an A/D and D/A interface circuit is established between the two circuits doing A/D and D/A data converting works so that the A/D and D/A interface circuit couples the analog circuit and the digital circuit together. Next, a first ground reference and a second ground reference are provided. In the method, a ground reference of the analog circuit and a ground reference of the A/D and D/A interface circuit are connected to the first ground reference, and a ground reference of the digital circuit is connected to the second ground reference. Then, a joint clock source is provided for simultaneously supplying clock pulses to the analog circuit, the digital circuit, and the A/D and D/A interface circuit, and a ground reference of the joint clock source is connected to the first ground reference.

The preferred embodiment of the present invention also provides a circuit architecture for minimizing a circuit element interference and stabilizing a circuit element within a TDD transceiver. The circuit architecture is described as follows. A communication medium is first placed between two communication data receiving and transmitting parties. The communication medium can be a wireless or a wiring medium within which a communication signal propagates through. Next, an analog circuit is established. The analog circuit is mainly used for receiving and transmitting the communication signal in different time periods, and for modulating and demodulating the communication signal during a communication signal transmitting and receiving process. Following the analog circuit, a digital circuit is built. The digital circuit is used for digital signal processing and for providing a layer of a communication protocol stack. In between the digital circuit and the analog circuit, an A/D and D/A interface circuit is built. The A/D and D/A interface circuit is a convertor that converts an analog signal to a digital signal and converts a digital signal to an analog signal so that the A/D and D/A interface circuit bridges the analog circuit and the digital circuit together. The circuit architecture also provides a first ground reference and a second ground reference to allow the analog circuit and the digital circuit to have different ground references. A ground reference in the analog circuit and a ground reference in the A/D and D/A interface circuit are connected to the first ground reference, and a ground reference in the digital circuit is connected to the second ground reference. Next, the circuit architecture provides a joint clock source that is a crystal oscillator to simultaneously supply clock pulses to the analog circuit, the digital circuit, and the A/D and D/A interface circuit. Most importantly, a ground of the joint clock source is connected to the first ground reference.

The preferred embodiment of the present invention is particularly effective in resolving the communication link integrity problem and the communication data rate suppressed problem addressed in the prior art section. By applying the joint clock coupling architecture addressed in the invention, a circuit element interference in a TDD transceiver is greatly suppressed, and a performance of a circuit element is stabilized; thereby, these named problems are resolved effectively and inexpensively. The version of the present invention can be used in a TDD transceiver fabrication, and can also be used in other radio frequency integrated circuit (RF IC)fabrication as needs.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. The drawings are as follows.

FIG. 1 provides a use of a TDD transceiver in data transmitting and receiving parties in a block diagram.

FIG. 2 depicts a communication protocol stack.

FIG. 3 demonstrates a joint clock source coupling architecture of the preferred embodiment of the present invention.

FIG. 4 illustrates a method of the preferred embodiment of the present invention in a flow chart diagram.

FIG. 5 depicts a TDD transceiver throughput rate without a use of a joint clock coupling architecture disclosed in the embodiment of the present invention.

FIG. 6 depicts a TDD transceiver throughput rate with a use of a joint clock coupling architecture disclosed in the embodiment of the present invention.

### DETAILED DESCRIPTION OF SPECIFIC EMBODIMENTS

As in debugging and trouble-shooting a design of a time division duplex radio frequency integrated circuit (TDD transceiver), a joint clock source coupling architecture is identified for suppressing a circuit element interference and for stabilizing a circuit element performance in the TDD transceiver. As a result, by using the joint clock source coupling architecture, a communication link integrity is ensured, a communication data throughput rate is noticeably increased.

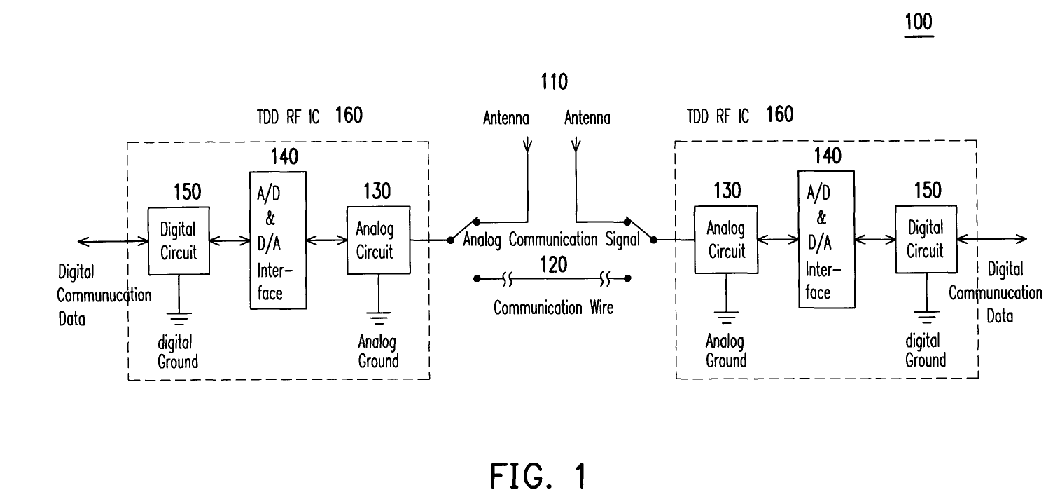

The preferred embodiment of the present invention provides a circuit as well as a method of the joint clock source coupling architecture for minimizing a circuit element interference and stabilizing a circuit element performance within a TDD transceiver. FIG. 1 illustrates a hardware layout of two hosts in communication in accordance with an embodiment of the present invention. It is noticed that a TDD transceiver 160 is used to transmit and to receive a communication signal. It is also noticed that one end of the TDD transceiver is an analog signal which is transmitted or received via a wiring 120 or a wireless 110 communication medium, and the other end of the TDD transceiver is a digital signal which is ready to be fed to a computer interface in general. Upon transmitting or receiving an analog signal via the communication medium, the TDD transceiver is first equipped with an analog circuit 130, then an analog-to-digital (A/D) and digital-to-analog (D/A) interface 140, and a digital circuit 150 to provide an A/D and D/A data flow path. Mainly, the analog circuit 130 is designed for receiving and transmitting an analog signal and for modulating and demodulating an analog signal. The digital circuit is used for doing digital signal processing and for providing a layer to a communication protocol stack, and the A/D and D/A interface provides a bridge connecting the analog circuit and the digital circuit together.

A Time Division Duplex (TDD) transceiver is a Radio Frequency Integrated Circuit (RF IC) accompanying with a digital circuit for digital data processing (DSP) and a digital-to-analog (D/A) analog-to-digital (A/D) interface. The TDD transceiver is used to transmit or to receive communication data at a time. Thereby, based on different divisions of time, communication data are transmitted or are received in the TDD transceiver. The TDD transceiver can be used in a wireless or a wiring communication network as depicted in FIG. 1. From an analytical point of view, the TDD transceiver can be decomposed into an analog portion of circuit, a digital portion of circuit, and an A/D and D/A interface circuit. A typical TDD transceiver of the preferred embodiment of the present invention is demonstrated in FIG. 3. In FIG. 3, the analog portion of circuit contains a switch 310, a down-convertor 315, an up-convertor 320, and a synthesizer 330. The synthesizer 330 further contains a voltage control oscillator (VCO). The digital portion of circuit contains a baseband processor 385, and a media access control (MAC) unit 390. The A/D and D/A interface circuit contains an A/D convertor 375, and a D/A convertor 380. A crystal oscillator 350 provides a joint clock source that simultaneously supplies clock pules to the analog portion of circuit, the A/D and D/A interface circuit, and the baseband processor 385.

An A/D convertor is a circuit element used to convert an analog signal to a digital signal. Similar to an A/D convertor, a D/A convertor is a circuit element that converts a digital signal to an analog signal. With a properly defined A/D convertor 375 and D/A convertor 380 pair between the analog portion and a digital portion of the TDD transceiver circuits, a digital data stream can be converted to an analog signal, and vice versa. Following a data path from the baseband processor 385 to the antenna 305, a digital data stream is first packed, converted, and transmitted through the antenna 305. The baseband processor 385 is a digital signal processing (DSP) unit doing a last step digital data stream packing up work before a digital data stream is converted to a baseband analog signal via the D/A convertor 380. After the D/A convertor 380 converts the digital data stream to the baseband analog signal, the up-convertor again transforms the baseband analog signal to a radio frequency signal before the baseband analog signal can be transmitted through the antenna 305 or a communication wire 120 to a remote host.

The radio frequency signal carrying the baseband analog signal is then transmitted through the antenna 305 or through the wire 120. Upon receiving the radio frequency signal, the remote host uses the same TDD transceiver system to try to recover the baseband analog signal from the radio frequency signal. The received baseband analog signal is then converted to a digital data stream via the A/D convertor. Referring to FIG. 3, the antenna 305 is used to transmit or to receive the radio frequency signal that carries the analog signal. During a receiving data time period, the switch 310 connects the antenna 305 to the down-convertor 315, and during a transmitting data time period, the switch 310 connects the antenna 305 to the up-convertor 320 so that data transmitting and data receiving in different time period share the same antenna. The down-convertor 315 is used for recovering the baseband analog signal from the radio frequency signal. The synthesizer 330 provides a carrier frequency signal to both down-convertor 315 and up-convertor 320. During a transmitting communication data period, for power saving purposes, the down-convertor 315 is turned off and the up-convertor 320 is turned on. The up-convertor 320 receives a baseband analog data signal from the D/A convertor, and modulates the baseband analog data signal with the carrier frequency signal to obtain a radio frequency transmitting signal. The radio frequency transmitting signal is then sent to the antenna 305 via the switch 3 10, and is therefore transmitting out through the antenna 305. Similarly, during a receiving communication data period, the up-convertor 320 is turned off, and the down-convertor 315 is turned on for power saving. Upon receiving a radio frequency transmitting signal via the antenna 305 and the switch 310, the down convertor 315 demodulates the received radio frequency data signal according to the carrier frequency signal that is supplied from the synthesizer 330 to obtain the baseband analog data signal. The received baseband analog data signal is then fed to the A/D convertor 375 so that the digital data stream is obtained. Via the baseband processor 385 and the media access control (MAC) unit 390, the digital data stream gets further processed and passed to a upper layer of a communication protocol stack.

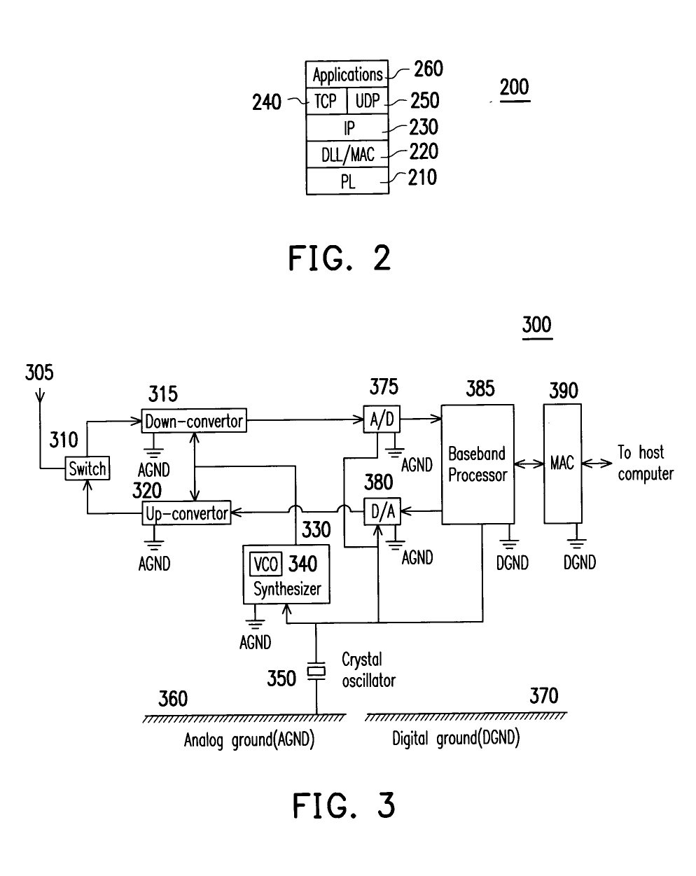

An example of a communication protocol stack is depicted in FIG. 2. The example is a typical Internet communication protocol stack 200. From the bottom up of the figure, the first layer is a physical layer (PL) 210. The second layer is a data link layer (DLL) or a media access control (MAC) layer. The third layer is an internet protocol (IP) layer. The forth layer is a transmission control protocol (TCP) and user datagram protocol (UDP) layer. Above the TCP/UDP joint layer, an application layer presents. A data path flow defined between the switch 310 to the baseband processor 385 can fit in a physical layer of a communication protocol stack, for instance, the physical layer (PL) 210 in FIG. 2. The MAC unit 390 in FIG. 3 corresponds to a second layer of a communication protocol stack, for instance, the MAC layer defined in the IEEE 802.11 communication stack. In short, the baseband processor 385 is a digital signal processing (DSP) unit, and the MAC unit 390 is a media access control (MAC) unit which is a communication layer defined above a physical layer.

It is noted that the baseband processor 385 and the media access control (MAC) unit 390 are grounded at a digital ground reference 370. The other circuit elements such as the switch 310, the down-convertor 315, the up-convertor 320, the synthesizer 330, the A/D convertor 375, and the D/A convertor 380, are all connected to an analog ground reference 360. It is also noticed that a crystal oscillator 350 acts as a joint clock source to supply clock pulses to both analog portion and digital portion of circuits in the TDD transceiver depicted in FIG. 3. Conventionally, a ground reference of the crystal oscillator 350 is connected at the digital ground 370, and un-anticipatively creates some unpredictable interference among the circuit elements in the TDD transceiver. This unpredictable interference suppresses a throughput rate of the TDD transceiver, and reduces a successful linking rate between two communication parties. It is noticed that the interference especially provides bad effects to the synthesizer 330. As a radio frequency signal gets transmitted or received, the up-convertor 320 or down-convertor 315 gets turned on or off. A turnaround transient of the up-convertor 320 and the down-convertor 315 accompanying with the interference causes a variation to a direct current (DC) power supply that supplies power to a voltage control oscillator (VCO) 340. As a consequence, the DC power supply variation cases VCO 340 frequency drift and forces the synthesizer 330 to re-lock the VCO frequency. As a result, during a VCO frequency re-lock process, a communication link may lose, and a throughput rate of the TDD transceiver is suppressed.

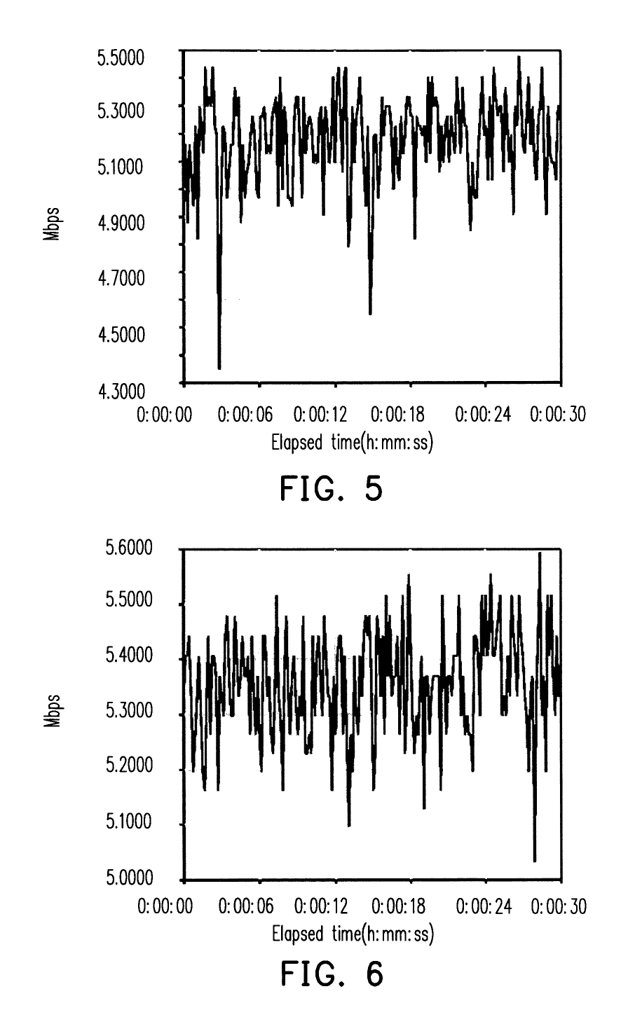

By connecting a ground reference of the joint clock source that is the crystal oscillator 350 in the preferred embodiment of the present invention to the analog ground reference 360, a circuit element interference within the TDD transceiver is greatly reduced. Thereby, a communication link is ensured and a throughput of the TDD transceiver is increased. As depicted in FIG. 5, a TDD transceiver average throughput rate of about 5.15 mega-bit-per-second (Mbps) is obtained by connecting the ground reference of the joint clock source 350 to the digital ground reference 370 in the TDD transceiver. As a contrast, in FIG. 6, a TDD transceiver average throughput rate of about 5.35 Mbps is obtained by connecting the ground reference of the joint clock source 350 to the analog ground reference 360 in the TDD transceiver. Apparently, by properly connecting the ground reference of the joint clock source to the analog ground reference 360, a 4% of throughput increment is obtained, and a circuit element interference in the TDD transceiver is minimized.

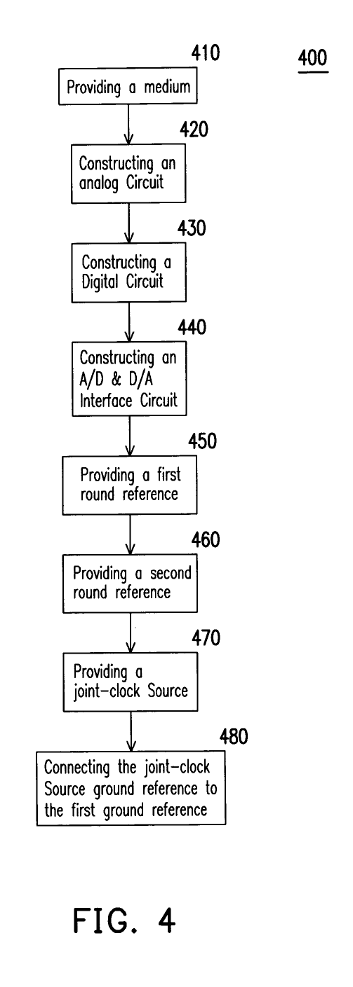

Accordingly, a method of minimizing a circuit element interference and stabilizing a performance of a circuit element is also provided in the preferred embodiment of the present invention. A flow chart diagram 400 demonstrates the method in FIG. 4. In step 410 of the method, a medium for a communication signal propagating back and forth through it is provided. Next, step 420 constructs an analog circuit for receiving and transmitting the communication signal through the medium at a time, and for modulating and demodulating the communication signal during a communication signal receiving and transmitting process. Step 430 constructs a digital circuit for digital signal processing, and step 440 provides an AID and a D/A interface so that the A/D and D/A interface couples the analog circuit and the digital circuit together. The method then provides a first ground reference so that all ground references of circuit elements in the analog circuit and in the A/D and D/A interface are connected to the first ground reference in step 450. In step 460, the method provides a second ground reference so that all ground references of circuit elements in the digital circuit are grounded to the second ground reference. Next, the method provides a joint clock source for supplying clock pluses to the analog circuit, the A/D and D/A interface, and the digital circuit in step 470, and connects a ground reference of the joint clock source to the first ground reference in step 480.

The embodiment of the present invention is particularly useful for minimizing a circuit element interference within a TDD transceiver; thereby, a performance of the TDD transceiver is improved. However, the embodiment of the present invention can also be used in other related radio frequency integrated circuit (RF IC) as is needed to provide a solution to minimize an unpredictable circuit element interference within a RF IC.

It will be apparent to those skilled in the art that various modifications and variations can be made to the structure or to the methods of the preferred embodiment of the present invention without departing from the scope or spirit of the invention. In view of the foregoing, it is intended that the present invention cover modifications and variations of this invention provided they fall within the scope of the following claims and their equivalents.

What is claimed is:

1. A method of minimizing a circuit element interference and stabilizing a performance of a circuit element within a Time Division Duplex (TDD) transceiver, which comprises:
providing a medium for a communication signal propagating back and forth through the medium;
constructing an analog circuit for receiving and transmitting the communication signal through the medium at a time, and for modulating and demodulating the communication signal during a communication signal receiving and transmitting process;
constructing a digital circuit for digital signal processing;
constructing an analog-to-digital (A/D) interface and a digital-to-analog (D/A) interface so that the interfaces couples the analog circuit and the digital circuit together;
providing a first ground reference so that all ground references of circuit elements in the analog circuit, in the A/D interface, and in the D/A interface are connected to the first ground reference;
providing a second ground reference so that all ground references of circuit elements in the digital circuit are grounded to the second ground reference;
providing a joint clock source for supplying clock pulses to the analog circuit, the digital circuit, the A/D interface, and the D/A interface; and
connecting a ground reference of the joint clock source to the first ground reference.

2. The method of claim 1, wherein the medium is an antenna and the communication signal propagates through the air.

3. The method of claim 1, wherein the medium is a communication wire where the communication signal propagates through the wire.

4. The method of claim 1, wherein the joint clock source is a crystal oscillator.

5. The method of claim 1, where in the constructing analog circuit step further comprises:
providing a switch for transmitting or receiving the communication signal in different time periods;
providing a down-convertor for converting the received communication signal to a baseband signal;
providing an up-convertor for converting a baseband signal to a radio frequency signal; and
constructing a synthesizer to provide the down-convertor and the up-convertor with a base frequency of signal so that the received and baseband communication signals are demodulated and modulated respectively.

6. The method of claim 1, where in the constructing digital circuit step further comprises:
providing baseband processor for digital signal processing; and
providing a media access control (MAC) unit.

7. The method of claim 1, wherein the A/D interface is an analog-to-digital convertor.

8. The method of claim 1, wherein the D/A interface is a digital-to-analog convertor.

9. A circuit architecture for minimizing a circuit element interference and stabilizing a performance of a circuit element within a TDD transceiver, which comprises:
a medium within which a communication signal propagates through;
an analog circuit for receiving and transmitting the communication signal in different time periods, and for modulating and demodulating the communication signal during a communication signal transmitting and receiving process;
a digital circuit for digital signal processing;
an A/D interface circuit and a D/A interface circuit for coupling the analog circuit and the digital circuit together;
a first ground reference on which all ground references of circuit elements of the analog circuit, the A/D interface circuit, and the D/A interface circuit are connected together;
a second ground reference on which all ground references of circuit elements of the digital circuit are connected together; and
a joint clock source to supply clock pluses to the analog circuit, the digital circuit, the A/D interface circuit, and the D/A interface circuit, and to have a ground reference of the joint clock source connected to the first ground reference.

10. The circuit architecture of claim 9, wherein the medium is an antenna and the communication signal propagates through the air.

11. The circuit architecture of claim 9, wherein the medium is a communication wire where the communication signal propagates through the wire.

12. The circuit architecture of claim 9, wherein the joint lock source is a crystal oscillator.

13. The circuit architecture of claim 9, wherein the analog circuit further comprises:
a switch for transmitting or receiving the communication signal in different time periods;
a down-convertor for converting the received communication signal to a baseband signal;
an up-convertor for converting a baseband signal to a radio frequency signal; and
a synthesizer for providing the down-convertor and the up-convertor with a base frequency of signal so that the received and baseband communication signals are demodulated and modulated respectively.

14. The circuit architecture of claim 9, wherein the digital circuit further comprises:
a baseband processor for digital signal processing; and
a media access control (MAC) unit.

15. The circuit architecture of claim 9, wherein the A/D interface is an analog-to-digital convertor.

16. The circuit architecture of claim 9, wherein the D/A interface is a digital-to-analog convertor.
